(19) United States
(12) Patent Application Publication
(10) Pub. No.: US 2003/0057457 A1
(43) Pub. Date: Mar. 27, 2003

(54) Semiconductor device having buried conductive layer and method of manufacturing thereof

(75) Inventors: Masaki Yamada, Kanagawa-ken (JP); Akihiro Kajita, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/003,114

(22) Filed: Dec. 6, 2001

(30) Foreign Application Priority Data
Sep. 27, 2001 (JP) P2001-298522

(51) Int. Cl. H01L 21/302; H01L 27/148; H01L 29/768; H01L 23/48; H01L 23/52; H01L 29/40

(52) U.S. Cl. 257/249; 438/692; 438/443; 257/250; 257/774

(57) ABSTRACT

A semiconductor device having a buried conductive layer and a method of manufacturing thereof are disclosed. In the semiconductor device, the buried conductive layer is formed in a first interlayer insulating layer. The conductive layer has a surface higher than a surface of the first interlayer insulating layer. Furthermore, the first interlayer insulating layer and the conductive layer are covered with an insulating film having a flat surface. On the insulating film, formed is a second interlayer insulating layer having a high etching selective ratio to the insulating film. The method of manufacturing the semiconductor device includes forming a first interlayer insulating layer on a semiconductor substrate, forming a trench in the first interlayer insulating layer, forming a conductive layer on the first interlayer insulating layer to bury the conductive layer in the trench, and polishing a surface of a resultant structure to form a flat surface to which the first interlayer insulating layer and the conductive layer are exposed. Furthermore, the method includes etching a damaged layer due to the polishing, forming an insulating film by coating on the surface of the resultant structure, and forming a second interlayer insulating layer, which has a high etching selective ratio to the insulating film, on the insulating film.

### CROSS REFERENCE TO RELATED APPLICATION

This application is based upon and claims the benefit of priority from Japanese Patent Application No. 2001-298522, filed on Mar. 27, 2001; the entire contents of which are incorporated herein by reference.

### BACKGROUND OF THE INVENTION

1. Field of the Invention

The present invention relates to a semiconductor device and a method of manufacturing thereof. Specifically, the present invention relates to a semiconductor device having a conductive layer formed by use of a burying method (damascene method) and to a method of manufacturing thereof.

2. Description of the Related Art

In recent years, many large-scale integrated (LSI) circuits are used in essential portions of equipments such as computers and communication equipments. Total performance of the equipment significantly depends on performance of a single unit of LSI. The performance of the single unit of LSI is improved by increasing an integration degree thereof. On the other hand, a problem has been caused by fine size of elements accompanied with integration. The problem is that high speed operation of LSI circuits is hindered by an increase in wiring resistance and RC delay caused by capacitance coupling between wiring lines.

In order to solve the problem, the wiring resistance or the capacitance between the wiring lines is required to be reduced. Accordingly, wiring materials of low resistances and insulating film materials of low dielectric constants have been widely employed. For example, as the wiring materials, instead of aluminum (Al) heretofore used, copper (Cu) has been employed, resistivity of which is lower than that of aluminum by about 35%. As the interlayer insulating film, SiOF films with relative dielectric constants k less than 3.6 or the like has been employed, instead of SiO₂ films with relative dielectric constants k not less than about 4.1.

Cu wiring has low resistance and has excellent electromigration resistance compared to Al wiring. However copper is diffused in Si substrates or the SiO₂ films at very high speed and the diffusion of copper sometimes has bad influences on transistor characteristics. Therefore, formation of a Cu wiring layer requires a structure, in which the periphery of the Cu wiring layer is covered with a barrier metal having an anti-diffusion effect and an insulating film.

For example, as shown in FIG. 1A, a first interlayer insulating layer 230 is formed on a semiconductor substrate layer 215, which has an insulating layer 220 as an element separation region on a surface of a substrate 210. When Cu wiring 250 is formed in the first interlayer insulating layer 230 by a burying method (damascene method), it is necessary that a barrier metal 240 is formed on the bottom and the side surfaces of a trench, into which the Cu wiring 250 is buried. Moreover, it is necessary that an exposed surface of the Cu wiring 250 is covered with an insulative anti-diffusion film 260.

Meanwhile, the anti-diffusion film 260 is also used as an etching stopper when a contact hole is formed in a second interlayer insulating layer 270. Therefore, a material of the anti-diffusion film 260 should be selected so that the second interlayer insulating layer 270 can be selectively etched to the anti-diffusion film 260. Recently, as the second interlayer insulating layer 270, SiOF with a low dielectric material is used; and as the anti-diffusion film 260, an SiN film or an SiC film formed by use of a CVD method or the like is mainly used.

However, such SiN film or SiC film, which is the conventional material of the anti-diffusion film, has a relative dielectric constant remarkably higher than that of the low dielectric interlayer insulating layer. Accordingly, even if the low dielectric material is used as the interlayer insulating layer, the capacity between wiring lines cannot be sufficiently reduced.

Furthermore, the Cu wiring formed by use of the damascene method includes a following problem.

In the case of forming the Cu wiring by use of the damascene method, after burying the conductive material in a wiring trench, a chemical mechanical polishing (CMP) process is carried out for smoothing a surface of a resultant structure. However, since the CMP process includes a mechanical treatment, as shown in FIG. 1A, micro mechanical damage 235 remains on the surface of the resultant structure. Particularly, the mechanical damage 235 remaining on the first interlayer insulating layer 230 is not subjected to etching or the like in subsequent processes and then remains. Accordingly, film exfoliation or the like is caused by such mechanical damage 235.

As shown in FIG. 1B, when a contact hole 280 is formed on the Cu wiring 250 by using the anti-diffusion film 260 as an etching stopper, if misalignment of the Cu wiring 250 and the contact hole 280 occurs, etching is sometimes progressed penetrating through the anti-diffusion film 260 as an etching stopper in a portion of the contact hole other than the Cu wiring 250. Accordingly, a deep trench (280B) is locally formed in the contact hole. In such a deep trench, insufficient burying is likely to occur, thus easily causing imperfect covering or the like of the Cu wiring.

These problems occurs not only for forming the Cu wiring, but also for forming a conductive layer such as metal wiring and metal gates formed by use of the damascene method.

### SUMMARY OF THE INVENTION

A semiconductor device according to a first aspect of the present invention includes a first interlayer insulating layer, a trench formed in the first interlayer insulating layer, and a conductive layer buried in the trench. The conductive layer has a surface thereof higher than a surface of the first interlayer insulating layer. Further, the semiconductor device includes an insulating film, which covers the first interlayer insulating layer and the conductive layer and has an approximately flat surface. Furthermore, the semiconductor device includes a second interlayer insulating layer formed on the insulating film. The second interlayer insulating layer has a high etching selective ratio to the insulating film.

A method of manufacturing a semiconductor device according to a second aspect of the present invention includes forming a first interlayer insulating layer, forming a trench in the first interlayer insulating layer, forming a conductive layer on the first interlayer insulating layer to bury the conductive layer in the trench, and polishing a surface of a resultant structure after forming the conductive layer to form a flat surface in which the first interlayer insulating layer and the conductive layer exposed. Thereafter, the method further includes etching a mechanically damaged layer, which is caused by the polishing and remains on a surface of the first interlayer insulating layer. Furthermore the method includes forming an insulating film having a flat surface on the surface of the resultant structure after the etching, and forming a second interlayer insulating layer on the insulating film. The second interlayer insulating layer has a high etching selective ratio to the insulating film.

A method of manufacturing a semiconductor device according to a third aspect of the present invention includes forming a first interlayer insulating layer, covering the first interlayer insulating layer with a protective film, forming a trench in the first interlayer insulating layer covered with the protective film, forming a conductive layer on a surface of a resultant structure after forming the trench to bury the conductive layer therein, and polishing the surface of the resultant structure after forming the conductive layer to form a flat surface to which the protective film and the conductive layer are exposed. Then, the method further includes etching the protective film and forming an insulating film, which has a flat surface, on the surface of the resultant structure after etching the protective film. Furthermore, the method further includes forming a second interlayer insulating layer on the insulating film. The second interlayer insulating layer has a high etching selective ratio to the insulating film.

### BRIEF DESCRIPTION OF THE DRAWINGS

FIGS. 1A and 1B are partially sectional views of a semiconductor device having a conventional buried conductive layer.

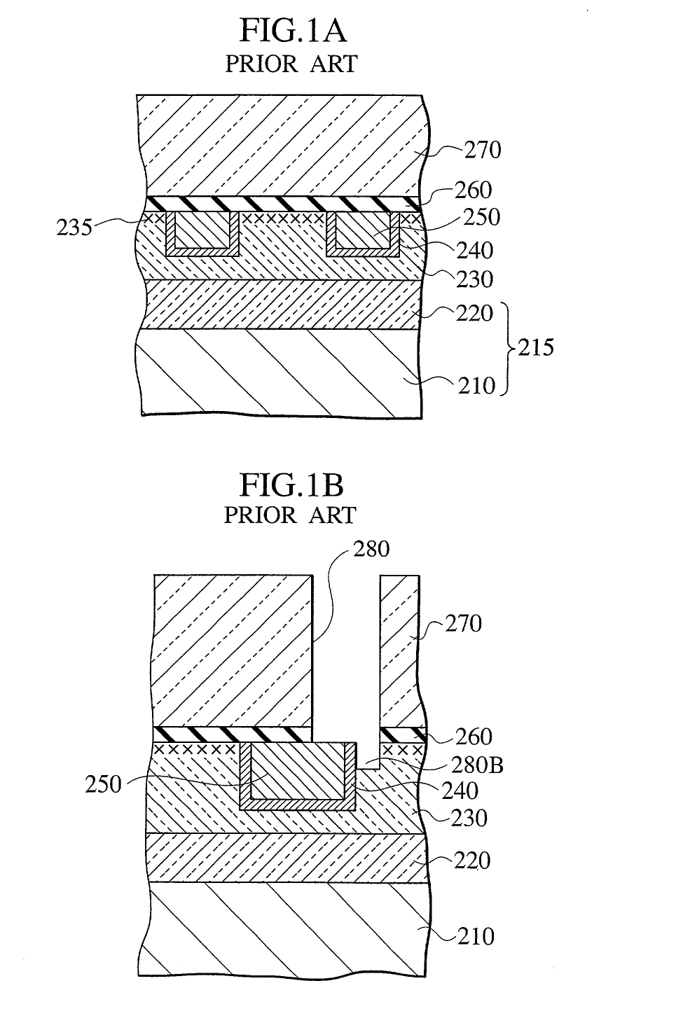

FIGS. 2A and 2B are partially sectional views of a semiconductor device according to a first embodiment of the present invention.

FIGS. 3A to 3E are partially sectional views showing each step of a method of manufacturing the semiconductor device according to the first embodiment of the present invention.

FIGS. 4A to 4E are partially sectional views showing each step of a method of manufacturing the semiconductor device according to a second embodiment of the present invention.

FIGS. 5A to 5C are partially sectional views showing each step of a method of manufacturing the semiconductor device according to a third embodiment of the present invention.

FIGS. 6A and 6B are constitutional views of a semiconductor manufacturing apparatus according to a fourth embodiment of the present invention

### DETAILED DESCRIPTION OF THE EMBODIMENTS

(First Embodiment)

Description will be made on a Cu wiring structure according to embodiments of the present invention with reference to the accompanying drawings.

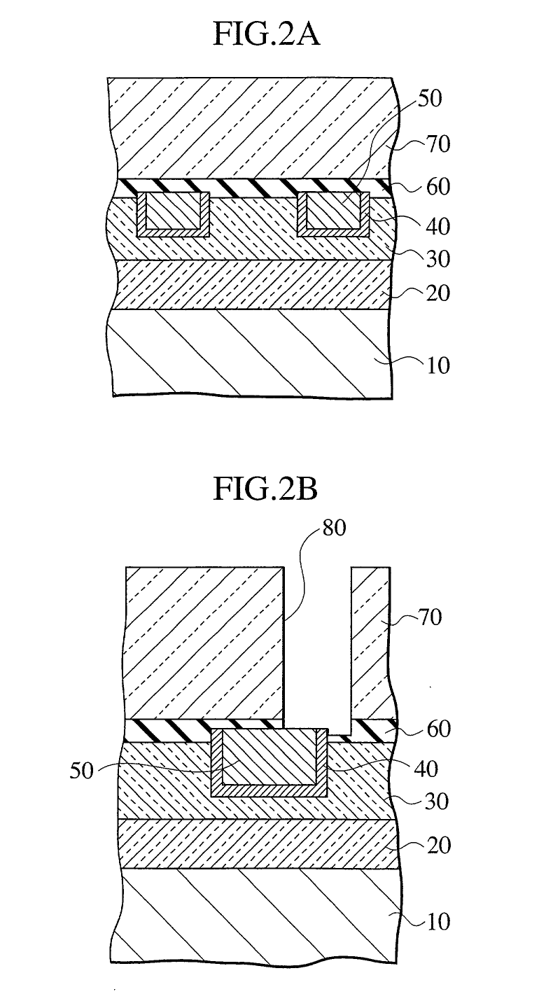

FIG. 2A shows a structure of a semiconductor device according to a first embodiment. Note that the drawing exemplifies a wiring layer formed on an insulating layer 20 as an element separation region, but a similar wiring structure may be formed on an activation region having functional elements formed therein.

As shown in FIG. 2A, in the semiconductor device according to the first embodiment, a first interlayer insulating layer 30 is formed on the insulating layer 20 as an element separation region. Wiring trenches are formed in the first interlayer insulating layer 30. Barrier metal 40 is formed on an inner wall of each wiring trench, and Cu wiring 50 is buried inside thereof.

Here, the semiconductor device of the first embodiment is characterized in that an exposed surface of the Cu wiring 50 is higher than that of the first interlayer insulating layer 30 therearound. Specifically, the surface of the first interlayer insulating layer 30, in which damage by a CMP process has conventionally remained, is selectively removed. The surface of the first interlayer insulating layer 30 is lowered and the surface of the Cu wiring 50 is relatively raised by a thickness of the removed surface of the first interlayer insulating layer.

The surfaces of the Cu wiring 50 and the first interlayer insulating layer 30 are covered with an insulative anti-diffusion film 60 for preventing diffusion of copper (Cu). In the first embodiment, the anti-diffusion film 60 is particularly made of a coating type material, so that good fluidity of the coating type material allows the formed anti-diffusion film 60 to have a flat surface without any influences of an uneven underlying layer. The anti-diffusion film 60 is formed to be thin on the Cu wiring 50 and to be thick on the first interlayer insulating layer 30.

Furthermore, on the anti-diffusion film 60, a second interlayer insulating layer 70 is formed. Note that only one wiring layer is shown in the drawing, but a plurality of wiring layers may be laminatedly formed, if necessary.

As the first and the second interlayer insulating layers 30 and 70 according to the first embodiment, materials having lower dielectric constants than SiO₂ are preferably used, such as methylpolysiloxane having, for example, a relative dielectric constant of 2.7. As the anti-diffusion film 60, a low dielectric material is preferred. In addition, for providing the anti-diffusion film 60 with a function as an etching stopper, a material thereof is preferably selected such that the second interlayer insulating layer 70 has a high etching selective ratio to the anti-diffusion film 60. The etching selective ratio means an etching rate ratio. In other words, when the second interlayer insulating layer 70 is etched faster than the anti-diffusion film 60 is, the second interlayer insulating layer 70 has a high etching selective ratio to the anti-diffusion film 60. Specifically, polyarylene, benzo cyclo-butene (BCB), and the like are cited as the material for the anti-diffusion film 60. Moreover, the anti-diffusion film 60 is simultaneously provided with a function of preventing oxidation of the Cu wiring.

FIG. 2B is a sectional view showing the semiconductor device according to the first embodiment when a contact hole 80 is formed on the Cu wiring 50.

In the case where the second interlayer insulating layer 70 is etched by using the anti-diffusion film 60 of the first embodiment as an etching stopper, as shown in FIG. 2B, misalignment of the contact hole 80 and the Cu wiring 50 sometimes occurs. However, since the anti-diffusion film 60 on the first interlayer insulating layer 30 is thick enough compared to the Cu wiring 50, the progress of etching is suppressed within the anti-diffusion film 60, even if overetching is carried out to some extent. Therefore, the contact hole 80 does not reach the underlying first interlayer insulating layer 30, penetrating through the anti-diffusion film 60. Accordingly, unlike the conventional device structure, a local deep trench is not formed in the contact hole 80, if misalignment of the contact hole 80 and the Cu wiring 50 occurs, thus a problem such as insufficient burying of the contact hole can be avoided.

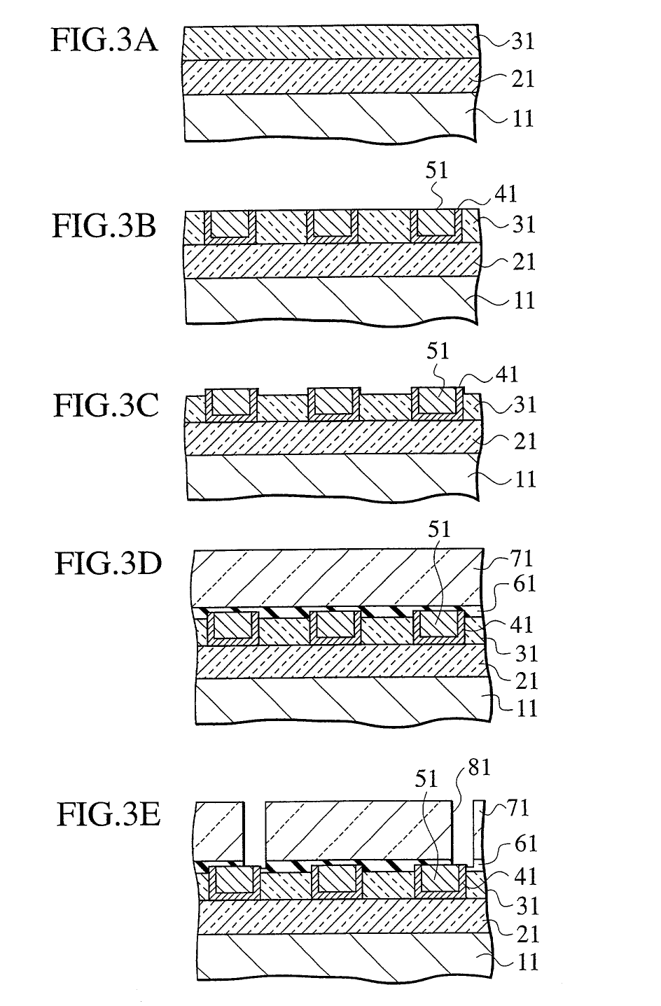

Next, description will be made on a method of manufacturing the semiconductor device according to the first embodiment with reference to FIGS. 3A to 3E. Note that a method of forming the Cu wiring will be mainly described herein while omitting description on a formation step of a element separation structure using a conventional method and a formation step of functional elements such as transistors.

First, as shown in FIG. 3A, a first interlayer insulating layer 31 is formed on an insulating layer 21 as an element separation region formed on a substrate 11. The first interlayer insulating layer 31 is preferably made of an inorganic material having a low dielectric constant. The first interlayer insulating layer 31 is made of methylpolysiloxane having a relative dielectric constant of 2.7 in a film thickness of about 200 nm by coating, for example.

Next, in the first interlayer insulating layer 31, wiring trenches corresponding to a predetermined Cu wiring pattern are formed by use of a photolithography process. Subsequently, a TaN film to be barrier metal 41 is formed, for example, in a thickness of about 10 nm on the surface of the resultant structure and the inner surfaces of these wiring trenches. Then a Cu film having a thickness of about 60 nm is formed thereon as a seed layer for electroplating. These films may be formed, for example, by use of sputtering or the like.

Thereafter, a Cu film having a thickness of about 600 nm is formed on the Cu seed layer by the electroplating. Subsequently, the surface of the resultant structure is polished by use of the CMP process in order to leave the Cu film only in the wiring trenches, thus forming a flat surface of the resultant structure, to which the first interlayer insulating layer 31 and the Cu wiring 51 are exposed as shown in FIG. 3B.

As shown in FIG. 3C, the surface of the first interlayer insulating layer 31 is selectively etched by about 10 nm to 50 nm, for example, by wet etching with diluted hydrofluoric acid. By such etching, a layer with mechanical damage due to the CMP process, remaining on the surface of the first interlayer insulating layer 31, is removed. Moreover, the exposed surfaces of the Cu wiring 51 and the barrier metal 41 are relatively raised with respect to the surface of the first interlayer insulating layer 31 therearound, thus making the surface of the resultant structure uneven.

Subsequently, as shown in FIG. 3D, an insulative anti-diffusion film 61 having a thickness of about 50 nm is formed by use of a coating method, on the resultant structure having the first interlayer insulating layer 31 and the Cu wiring 51 formed thereon. Furthermore, on the anti-diffusion film 61, a second interlayer insulating layer 71 having a thickness of about 200 nm is formed by use of a coating method. As the material of the second interlayer insulating layer 71, methylpolysiloxane, which is a low dielectric material, is preferably used similarly to the first interlayer insulating layer.

As the material of the anti-diffusion film 61, polyarylene or benzo cyclo-butene is preferably used, because it is a coating type material with a low dielectric constant and has a function of preventing diffusion of copper (Cu) and serving as an etching stopper.

Since the anti-diffusion film 61 is formed by coating with the coating type material, the film may be formed to have a flat surface. Accordingly, the anti-diffusion film 61 is formed to be thin on the Cu wiring 51 and to be thick on the first interlayer insulating layer 31. Note that for the coating method, a dropping method may be used, in which a coating liquid is dropped onto the substrate by predetermined amounts at predetermined intervals, in addition to a coating method using a spin coater or the like.

Thereafter, as shown in FIG. 3E, contact holes 81 are formed in the second interlayer insulating layer 71 and the anti-diffusion film 61 in order to connect necessary portions on the Cu wiring 51 and wiring of an upper layer. At this time, as shown in FIG. 3E, even in the case of misalignment of each contact hole 81 and the Cu wiring 51, since the anti-diffusion film 61 is formed to be thick in a portion of the contact hole other than the Cu wiring 51, the progress of etching is sufficiently suppressed within the anti-diffusion film 61 even if overetching is carried out. Accordingly, formation of a local deep portion in the contact hole 81 is prevented.

As described above, in the wiring structure and the wiring formation method according to the first embodiment, the mechanically damaged layer, generated by the CMP process, on the surface of the first interlayer insulating layer 31 is removed by etching, whereby a problem such as film exfoliation caused by the remaining mechanically damage layer is prevented.

The anti-diffusion film 61 can be formed to be thin on the Cu wiring 51 and to be thick on the first interlayer insulating layer 31 because of good fluidity of the coating type material thereof. Accordingly, even if misalignment occurs in the formation of the contact holes, the sufficient thickness of the anti-diffusion film 61 prevents the progress of etching into the first interlayer insulating layer 31, thus preventing a problem such as imperfect burying of the contact holes.

Furthermore, in the wiring structure according to the first embodiment, the Cu wiring 51 of low resistance is formed as a wiring layer, and the anti-diffusion film 61 as well as the first and the second interlayer insulating layers 31 and 71 are made of the material of a low dielectric constant. Accordingly, RC delay of the wiring can be remarkably improved.

(Second Embodiment)

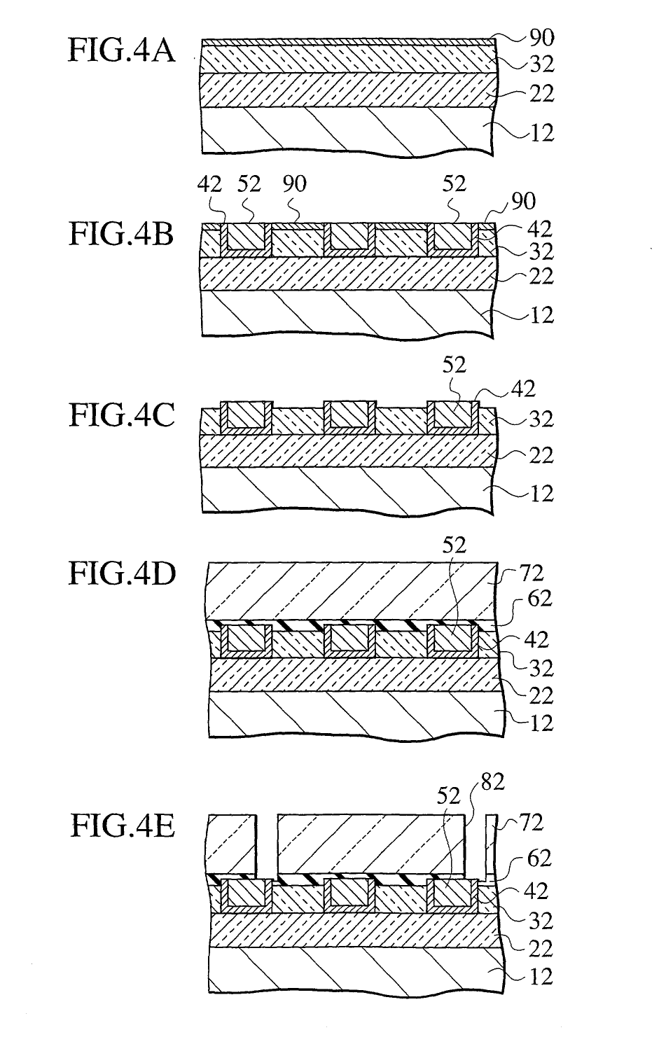

A semiconductor device according to a second embodiment has the same structure as the semiconductor device according to the first embodiment shown in FIGS. 2A and 2B, however a method of manufacturing thereof is different from that of the first embodiment. With reference to FIGS. 4A to 4E, description will be made below on the method of manufacturing the semiconductor device according to the second embodiment.

As shown in FIG. 4A, a first interlayer insulating layer 32 is formed on an insulating layer 22 as an element separation region formed on a substrate 12. Subsequently, a cap layer 90 as a protective layer is formed on the first interlayer insulating layer 32. The cap layer 90 is a layer for protecting the first interlayer insulating layer 32 from mechanical damage generated in the CMP process to be carried out later. The cap layer 90 may be an insulating film or a conductive film as long as the cap layer 90 works as the protective film and is not limited by an electrical property thereof. For example, an SiO₂ film having a thickness of about 50 nm to 100 nm formed by a CVD method may be used for the cap layer 90. Note that the first interlayer insulating layer 32 can be formed under the same conditions as those of the first embodiment.

Subsequently, wiring trenches corresponding to a predetermined Cu wiring pattern are formed by use of a photolithography process in the first interlayer insulating layer 32 covered with the cap layer 90. A TaN film, for example, is then formed as barrier metal 42 on a surface of a resultant structure including inner surfaces of the wiring trenches. On the barrier metal 42, a Cu film is formed as a seed layer for electroplating. Moreover, a Cu film is formed on the Cu seed layer to be buried in the wiring trenches by electroplating. Note that formation conditions such as film thicknesses of the barrier metal 42 and the Cu film can be similar to those in the first embodiment.

Furthermore, the surface of the resultant structure is polished by use of the CMP method to form a flat surface of the resultant structure, to which the cap layer 90 and the Cu wiring 52 are exposed as shown in FIG. 4B.

Subsequently, as shown in FIG. 4C, the cap layer 90 is removed by etching with diluted hydrofluoric acid. As a result, the exposed surface of the first interlayer insulating layer 32 is lowered with respect to that of the Cu wiring 52 by a thickness of the removed cap layer 90. Moreover, a mechanically damaged layer due to the CMP process dose not exist on the exposed surface of the first interlayer insulating layer 32.

The subsequent processes are the same as those of the manufacturing method according to the first embodiment. Specifically, as shown in FIG. 4D, an insulative anti-diffusion film 62 having a thickness of about 50 nm is formed by coating on the resultant structure, in which the first interlayer insulating layer 32 and the Cu wiring 52 are formed. Furthermore, on the anti-diffusion film 62, a second interlayer insulating layer 72 having a thickness of about 200 nm is formed.

Similarly to the first embodiment, preferably, methylpolysiloxane is used for the second interlayer insulating layer 72; and polyarylene is used for the anti-diffusion film 62.

Also in the method of manufacturing according to the second embodiment, since the anti-diffusion film 62 is formed by coating with a coating type material, a layer having a flat surface can be formed. As a result, the anti-diffusion film 62 is formed to be thin on the Cu wiring 52 and to be thick on the first interlayer insulating layer 32.

Thereafter, as shown in FIG. 4E, contact holes 82 are formed in the second interlayer insulating layer 72 and the anti-diffusion film 62 in order to connect necessary portions of the Cu wiring 52 and wiring of an upper layer. At this time, as shown in FIG. 4E, if misalignment of each contact hole 82 and the Cu wiring 52 occurs, since the anti-diffusion film 62 is formed to be thick in a portion of the contact hole other than the Cu wiring 51, even if overetching is carried out, the progress of etching is sufficiently suppressed within the anti-diffusion film 62. Accordingly, formation of a local deep portion in each contact hole 82 is prevented, whereby a problem such as insufficient burying of the contact holes is prevented.

An SiO₂ film used for the cap layer 90 as a mechanical protective film in the above second embodiment may be further provided with a function as a hard mask in a photo etching process or with a function as an anti-reflection film against a resist film.

According to the semiconductor device of the second embodiment and the method of manufacturing thereof, similar effects to the first embodiment can be obtained. In addition, since the cap layer 90 is used, the mechanical damage can be further surely prevented from remaining in the first interlayer insulating layer 32. Furthermore, respective heights of the surfaces of the first interlayer insulating layer 32 and the Cu wiring 52 are maintained with good accuracy.

(Third Embodiment)

A semiconductor device according to a third embodiment has a substantially similar structure to the semiconductor device according to the first embodiment shown in FIGS. 2A and 2B. In this embodiment, for the anti-diffusion film, the coating type material is not used, but an inorganic film formed by use of the CVD method is used instead.

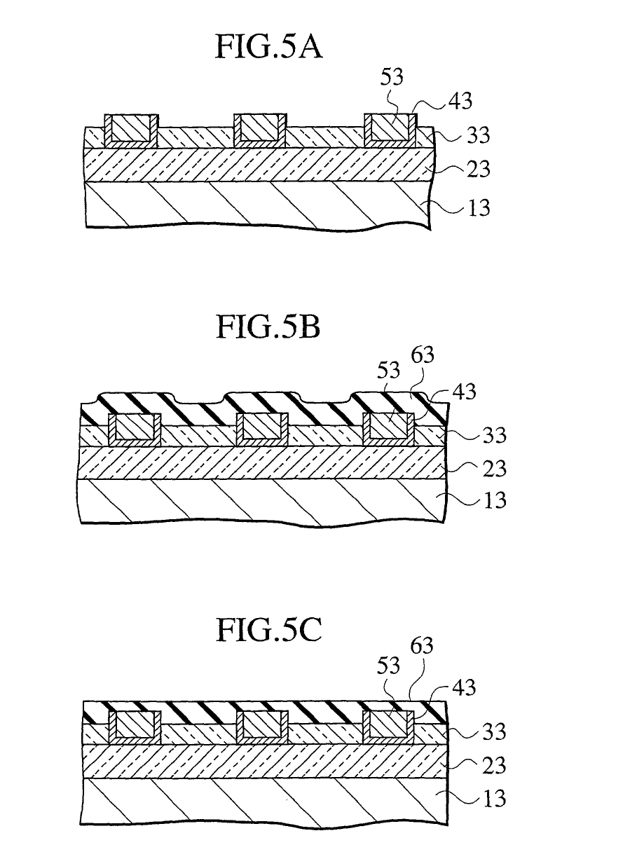

With reference to FIGS. 5A to 5C, description will be made below on a method of manufacturing the semiconductor device according to the third embodiment. A first interlayer insulating layer 33 is formed on an insulating layer 23, which is an element separation region formed on a substrate 13. The first interlayer insulating layer 33, wiring trenches, barrier metal 43 buried in the wiring trenches, and Cu wiring 53 may be formed under conditions similar to those in the first embodiment.

Furthermore, a structure as shown in FIG. 5A is formed, in which an exposed surface of the Cu wiring 53 is higher than an exposed surface of the first interlayer insulating layer 33. For formation of such a structure, either method of the first embodiment and the second embodiment may be employed.

As shown in FIG. 5B, in the method of manufacturing the semiconductor device according to the third embodiment, an SiN film and an SiC film are formed as an anti-diffusion film 63 by use of the CVD method as heretofore. The CVD method provides a film having good step coverage, and the anti-diffusion film 63 is formed to have an uneven surface reflecting the underlying uneven surface.

Then, the surface of the resultant structure is to be flatted by use of the CMP process. As a result, the anti-diffusion film 63 having a substantially flat surface as shown in FIG. 5C can be formed. Specifically, the anti-diffusion film 63 can be formed to be thin on the Cu wiring 53 and to be thick on the first interlayer insulating layer 33.

Accordingly, a second interlayer insulating layer 73 is formed on the anti-diffusion film 63 flatted similarly to the first and the second embodiments. Even if misalignment occurs in formation of necessary contact holes, since the anti-diffusion film 63 is formed to be thick in a portion of the contact hole other than the Cu wiring 53, the progress of etching can be sufficiently suppressed within the anti-diffusion film 63 even in the case of performing overetching. As the result, generation of a local deep portion in a contact hole is prevented, whereby a problem such as insufficient burying of the contact holes is prevented.

In the first to the third embodiments, the case of forming the Cu wiring by use of the damascene method has been described as an example. In the case of forming the other metal wiring as well as the Cu wiring by use of the damascene method, the methods of these embodiments are effective in removing the damaged layer, which is generated due to the CMP process and remaining in the interlayer insulating film. Also, the methods of these embodiments are effective in preventing the formation of a local deep portion in the contact hole due to misalignment in the formation of the contact hole. Moreover, the methods of these embodiments can be applied to metal gate electrodes or the like formed by use of the damascene method as well as the wiring.

(Fourth Embodiment)

In a fourth embodiment, description will be made on an example of a semiconductor manufacturing apparatus suitable for the manufacturing methods according to the above first and second embodiments.

As described above, in the semiconductor manufacturing method according to the first embodiment, the CMP process is carried out for forming a buried wiring layer. The CMP process is followed by a removal process of the damage layer of the first interlayer insulating layer, a formation process of the anti-diffusion film, and a formation process of the second interlayer insulating layer. The damage layer can be removed by wet etching. Each of the formation processes of the anti-diffusion film and the second interlayer insulating layer includes a coating step and an annealing step. Therefore, the following steps are carried out after the CMP process: 1) wet etching step for removing the damage layer, 2) coating step of the anti-diffusion film, 3) annealing step of the anti-diffusion film, 4) coating step of the second interlayer insulating layer, and 5) annealing step of the second interlayer insulating layer. These five sequential steps are carried out under atmospheric pressure, not requiring a high vacuum chamber.

In the case of using the semiconductor manufacturing method according to the second embodiment, the wet etching step is first carried out for removing the cap layer after the CMP process. The subsequent steps are sequentially carried out until the annealing step of the second interlayer insulating layer. The subsequent steps are the same as those in the first embodiment, and carried out under the atmospheric pressure, not requiring a high vacuum chamber.

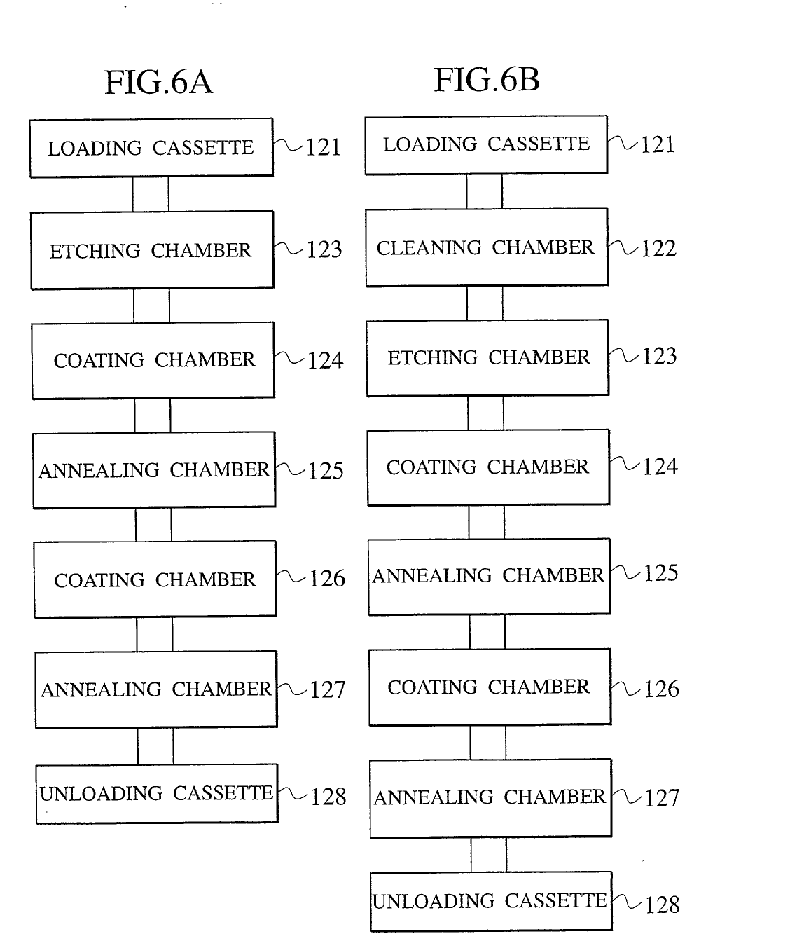

As shown in FIG. 6A or FIG. 6B, processing units (processing chambers) for the above respective steps, requiring no high pressure chamber, are arranged in an order of the steps. And the processing chambers are connected with each other by substrate carriers. Thus these chambers construct a product line capable of processing each wafer one after another. Since high vacuum is not necessary in each of the processing chambers, wafers are easily carried between the respective processing chambers. Accordingly, production efficiency is remarkably improved. Next, with reference to the drawings, the semiconductor manufacturing apparatus according to the fourth embodiment will be described more specifically.

As shown in FIG. 6A, the semiconductor manufacturing apparatus includes a loading cassette 121 for loading a substrate, an etching chamber 123, a coating chamber 124, an annealing chamber 125, a coating chamber 126, an annealing chamber 127, and an unloading cassette 128 for unloading the substrate, which are arranged in the order of the manufacturing steps. These processing chambers are connected with each other by the substrate carriers.

In the loading cassette 121, a substrate to be processed is set. The substrate was subjected to the processes on and before the CMP process in the first and the second embodiments, for example. The substrate is carried one after another to the etching chamber 123 through the carrier. The etching chamber 123 is provided with a tank containing an etching solution such as diluted hydrofluoric acid, a tank for washing or a shower unit for washing, a spin drying unit, and the like. The substrate is subjected to etching of the surface of the first interlayer insulating layer or etching of the cap layer, while passing the etching chamber 123.

The substrate leaving the etching chamber 123 is carried to the coating chamber 124, where the anti-diffusion film is coated on the surface of the substrate with a spin coater or the like, for example. The substrate is then moved to the annealing chamber 124, where volatilization of a solvent in a coated solution for the anti-diffusion film or a heat treatment for a crosslinking reaction or a polymerization reaction of the anti-diffusion film is performed. As to the atmosphere of the annealing chamber 124, an inert gas atmosphere containing nitrogen, argon and the like is preferably used, and oxygen partial pressure thereof is desirably controlled to be a low partial pressure of 100 ppb or lower. Such a gas atmosphere may be obtained, for example, by a method such as spraying the inert gas in a form of a shower on the substrate.

Subsequently, the substrate is carried to the coating chamber 126, where the surface of the substrate is coated with the second interlayer insulating layer. Furthermore, the substrate is moved to the annealing chamber 127, and volatilization of a solvent in the second interlayer insulating layer or a heat treatment for a crosslinking reaction or a polymerization reaction of the interlayer insulating layer is performed. It is desirable that the atmosphere of the annealing chamber 127 is an inert gas atmosphere containing nitrogen, argon and the like, and that the oxygen partial pressure thereof is controlled to be 100 ppb or lower, similarly to the annealing chamber 125 for the anti-diffusion film.

After annealing of the second interlayer insulating layer, the substrate is carried to the unloading cassette 128 to be carried out of the apparatus.

As shown in FIG. 6B, the apparatus may be provided with a cleaning chamber 122 between the loading cassette 121 and the etching chamber 123. The cleaning chamber 122 includes, for example, a tank containing hydrochloric acid, a tank containing pure water, and further a spin dryer, for the purpose of cleaning the substrate.

By using the semiconductor manufacturing apparatus according to the above fourth embodiment, since the processing chambers are connected in the order of the processing procedure, after the CMP process, the steps from the etching step of the first interlayer insulting layer or the cap layer to the formation step of the second interlayer insulating layer can be consistently carried out as sequential steps. Thus, throughput thereof can be improved.

Note that a kind of the etching solution used in the etching chamber 123 can be properly changed depending on a kind of the material to be etched. In FIG. 6B, cleaning of the surface of the substrate and etching thereof are carried out in the separate processing chambers. However, these steps may be carried out in one processing chamber by changing chemical solutions used therein. In this case, there is a merit of reduction of a space for the apparatus.

The annealing of the anti-diffusion film and the annealing of the second interlayer insulating layer are carried out in the separate annealing chambers 125 and 127, respectively. However, it is possible to previously subject the anti-diffusion film only to baking and then to carry out curing thereof at the same time of curing of the second interlayer insulating layer.

Furthermore, if a plurality of processing chambers for each step are provided in parallel, the processing speed can be further increased.

Description has been made on the first to fourth embodiments, but it is obvious to those skilled in the art that the semiconductor device and the method of manufacturing thereof according to the present invention is not limited to the description herein, and substitution of materials, modification or the like is possible.

As described above, according to the semiconductor device of the present invention, an insulating film is formed to be thick on the surface of the first interlayer insulating layer and to be thin in the conductive layer. Accordingly, in the case of forming the contact holes on the conductive layer by use of the insulating film as an etching stopper, even if misalignment thereof occurs, the progress of etching is suppressed by the thick insulating film on the surface of the first interlayer insulating layer, thus preventing the imperfect burying attributable to the formation of the local deep trench in each of the contact holes or the like. Therefore, the semiconductor device with high yields can be provided.

Furthermore, according to the method of manufacturing the semiconductor device of the present invention, since the mechanically damaged layer does not remain on the surface of the first interlayer insulting layer, occurrence of the film exfoliation or the like can be prevented. Moreover, because of the formation of the insulating film having a flat surface, the insulating film can be formed to be thin on the conductive layer and to be thick on the first interlayer insulating layer. Accordingly, in the case of forming the contact holes in the conductive layer by use of the insulating film as an etching stopper, even if misalignment thereof occurs, the progress of etching is suppressed by the thick insulating film on the surface of the first interlayer insulating layer, thus preventing the imperfect burying caused by the formation of the local deep trench in each of the contact holes or the like. Therefore, the semiconductor device with high yields can be provided.

Still furthermore, when the Cu wiring is used as the conductive layer and the low dielectric material is used as the insulating film, the RC delay can be reduced.

What is claimed is:

1. A semiconductor device comprising:
a first interlayer insulating layer;
a trench formed in the first interlayer insulating layer;
a conductive layer buried in the trench, the conductive layer having a surface thereof higher than a surface of the first interlayer insulating layer;
an insulating film having a flat surface and covering the first interlayer insulating layer and the conductive layer; and
a second interlayer insulating layer formed on the insulating film, the second interlayer insulating layer having a high etching selective ratio to the insulating film.

2. The semiconductor device according to claim 1, wherein a film thickness of the insulating film on the first interlayer insulating layer is greater than that on the conductive layer.

3. The semiconductor device according to claim 1, wherein the insulating film is made of a coating type material.

4. The semiconductor device according to claim 1, wherein the insulating film has an effect of preventing diffusion of a conductor material in the conductive layer.

5. The semiconductor device according to claim 1, wherein at least any one of the first interlayer insulating layer and the second interlayer insulating layer is made of an insulating material having a relative dielectric constant lower than that of an SiO₂ film.

6. The semiconductor device according to claim 1, wherein the insulating film is made of an insulating material having a relative dielectric constant lower than that of an SiO₂ film.

7. The semiconductor device according to claim 1, wherein the conductive layer includes a barrier metal layer.

8. The semiconductor device according to claim 1, wherein the conductive layer includes a Cu wiring layer.

9. The semiconductor device according to claim 1, wherein at least any one of the first interlayer insulating layer and the second interlayer insulating layer is made of methylpolysiloxane.

10. The semiconductor device according to claim 1, wherein the insulating layer is made of any one of polyarylene and benzo cyclo-butene.

11. A method of manufacturing a semiconductor device, comprising:
forming a first interlayer insulating layer;
forming a trench in the first interlayer insulating layer;
forming a conductive layer on the first interlayer insulating layer and burying the conductive layer in the trench simultaneously;
polishing a surface of a resultant structure after the formation of the conductive layer and forming a flat surface, to which the first interlayer insulating layer and the conductive layer are exposed;
etching a mechanically damaged layer due to the polishing, the mechanically damaged layer remaining on a surface of the first interlayer insulating layer;
forming an insulating film having a flat surface on the surface of the resultant structure after the etching; and
forming a second interlayer insulating layer, having a high etching selective ratio to the insulating film, on the insulating film.

12. The method according to claim 11, wherein the insulating film is formed by use of a coating method.

13. The method according to claim 11, further comprising:
partially etching the second interlayer insulating layer and the insulating film to form a contact hole having a bottom portion, to which at least a part of the conductive layer is exposed.

14. The method according to claim 11, wherein the insulating film is made of a material having an effect of preventing diffusion of a conductor material in the conductive layer.

15. The method according to claim 11, wherein at least any one of the first interlayer insulating layer and the second interlayer insulating layer is made of a material having a relative dielectric constant lower than that of an SiO₂ film.

16. The method according to claim 11, wherein the insulating film is made of a material having a relative dielectric constant lower than at least that of an SiO₂ film.

17. The method according to claim 11, wherein at least any one of the first interlayer insulating layer and the second interlayer insulating layer is made of methylpolysiloxane.

18. The method according to claim 11, wherein the conductive layer includes a barrier metal layer.

19. The method according to claim 11, wherein the conductive layer includes a Cu wiring layer.

20. The method according to claim 11, wherein the etching, the formation of the insulating layer, and the formation of the second interlayer insulating layer are carried out under atmospheric pressure.

21. A method of manufacturing a semiconductor device, comprising:
forming a first interlayer insulating layer;
covering a surface of the first interlayer insulating layer with a protective film;
forming a trench in the first interlayer insulating layer covered with the protective film;
forming a conductive layer on a surface of a resultant structure after the formation of the trench and burying the conductive layer in the trench;
polishing the surface of the resultant structure after the formation of the conductive layer and forming a flat surface, to which the protective film and the conductive layer are exposed;
etching the protective film;
forming an insulating film having a flat surface on the resultant structure after the etching the protective film; and
forming a second interlayer insulating layer, having a high etching selective ratio to the insulating film, on the insulating film.

22. The method according to claim 21, wherein the insulating film is formed by use of a coating method.

23. The method according to claim 21, wherein the protective film is an SiO₂ film.

24. The method according to claim 21, wherein the insulating film has an effect of preventing diffusion of a conductor material in the conductive layer.

25. The method according to claim 21, wherein at least any one of the first interlayer insulating layer and the second interlayer insulating layer is made of a material having a relative dielectric constant lower than that of an SiO₂ film.

26. The method according to claim 21, wherein the insulating film has a relative dielectric constant lower than at least that of an SiO₂ film.

27. The method according to claim 21, wherein at least any one of the first interlayer insulating layer and the second interlayer insulating layer is made of methylpolysiloxane.

28. The method according to claim 21, wherein the conductive layer includes a barrier metal layer.

29. The method according to claim 21, wherein the conductive layer includes a Cu wiring layer.

30. The method according to claim 21, wherein the etching, the formation of the insulating layer, and the formation of the second interlayer insulating layer are carried out under atmospheric pressure.
